(19) United States
(12) Patent Application Publication
(10) Pub. No.: US 2026/0127343 A1
(43) Pub. Date: May 7, 2026

(54) INTERFACING METHOD FOR RTL SIMULATION OF INTEGRATED CIRCUITS AND SYSTEM PERFORMING SAME

(71) Applicant: Baum Design Systems Co., Ltd., Seoul (KR)

(72) Inventors: In Hak HAN, Daejeon (KR); Ju Hyeong PARK, Daejeon (KR)

(21) Appl. No.: 19/302,106

(22) Filed: Aug. 18, 2025

(30) Foreign Application Priority Data
Nov. 6, 2024 (KR) 10-2024-0155823

(51) Int. Cl. G06F 30/327

(52) U.S. Cl. CPC G06F 30/327

(57) ABSTRACT

The present disclosure relates to an interfacing method for RTL simulation of an integrated circuit and a system performing the same. The method comprises: obtaining a clock gating time during which a clock supplied to the integrated circuit is gated; obtaining a data holding time during which the clock is not gated but input data do not switch; and providing a metric corresponding to a ratio, within a unit time, occupied by the clock gating time and the data holding time.

### CROSS-REFERENCE TO RELATED APPLICATION

This application claims priority to and the benefit of Korean Patent Application No. 10-2024-0155823, filed on Nov. 6, 2024, the disclosure of which is incorporated herein by reference in its entirety.

### BACKGROUND

### Technical Field

The present disclosure relates to a method for interfacing Register Transfer Level (RTL) simulation of an integrated circuit, and more particularly, to a method for interfacing various metrics that facilitate RTL simulation and to a system that performs the same.

### Background Art

An integrated circuit (IC) is an electronic device in which diverse functions such as computation and storage are integrated on a single semiconductor chip. As society becomes increasingly sophisticated, various types of mobile devices are being developed. By incorporating integrated circuit devices, mobile devices pursue miniaturization and weight reduction. A drawback of mobile devices is that they rely on limited power sources such as batteries. To extend the operating lifetime of mobile devices, research is being conducted on both increasing battery capacity and low-power design of integrated circuit devices.

Predicting the power consumption of integrated circuit devices is a prerequisite to achieving low-power design. For this purpose, the RTL simulation method is utilized. RTL design is a descriptive technique that, when designing an integrated circuit, specifies the data flow and the logical operations that process the data. Such RTL design utilizes a clock gating technique. Clock gating is an important technique for reducing power consumption in digital circuits. When a portion of the circuit is not in use, the clock signal to that portion is disabled, thereby reducing dynamic power consumption. If a part of the circuit is unnecessary for a certain period, clock gating can block the clock signal to that part, thereby preventing unnecessary power consumption.

Various indices such as Clock Gating Efficiency (CGE) and Operational Clock Gating Ratio (OCGR) have been developed to utilize the clock gating technique efficiently. However, these indices fail to reflect whether data switching occurs, and therefore are insufficient as representative indicators for efficient clock gating.

### SUMMARY

### Technical Problem

A technical objective of the present disclosure is to provide a method for interfacing a metric that can simultaneously reflect both clock gating status and data switching status, and to provide a system performing the same.

Another technical objective of the present disclosure is to provide various interfacing methods that can efficiently present a metric to a user.

### Technical Solution

An interfacing method for Register Transfer Level (RTL) design simulation of an integrated circuit according to the technical idea of the present disclosure may include: obtaining a clock gating time during which a clock is gated with respect to the integrated circuit; obtaining a data holding time during which the clock is not gated and input data does not switch; and providing a metric corresponding to a ratio of the clock gating time and the data holding time to a unit time

In one embodiment, the metric may be determined according to the equation below:

$$M = \frac{{t}_{g} + {t}_{c}}{{t}_{s}}$$

Wherein t_{g} refers to the clock gating time, t_{c} refers to the data holding time, and tₛ refers to the unit time.

In one embodiment, the method may further include: calculating a second metric corresponding to a clock gating ratio; receiving a scenario time; and, for the scenario time, interfacing a graph of the second metric per unit time.

In one embodiment, the method may further include: receiving a target metric value; and indicating, using an indicator, a unit time during which the second metric does not satisfy the target metric value.

In one embodiment, the method may further include: receiving a selection instruction for the indicator; and displaying an expanded graph in which a time axis of a unit time corresponding to the indicator is extended based on the selection instruction, wherein the indicator highlights corresponding time interval with a predetermined color and the expanded graph is also highlighted with the predetermined color.

In one embodiment, interfacing the graph of the second metric may include: calculating the second metric per unit time for a first RTL circuit; providing a first graph depicting the second metric per unit time for the first RTL circuit along a time flow of the clock; calculating the second metric per unit time for a second RTL circuit; providing a second graph depicting the second metric per unit time for the second RTL circuit along a time flow of the clock; and indicating unit times that are not identical between the first graph and the second graph.

In one embodiment, indicating the unit times that are not identical between the first graph and the second graph may include: highlighting, with a first color, unit times in which the second metric per unit time for the first RTL circuit is higher than the second metric per unit time for the second RTL circuit; and highlighting, with a second color, unit times in which the second metric per unit time for the first RTL circuit is lower than the second metric per unit time for the second RTL circuit.

In one embodiment, interfacing the graph of the second metric may include: calculating the second metric per unit time for a first clock domain in the RTL circuit to which a first clock is applied; calculating the second metric per unit time for a second clock domain in the RTL circuit to which a second clock is applied; and indicating the second metric for each of the first clock domain and the second clock domain.

In one embodiment, interfacing the graph of the second metric may further include: calculating an integrated metric by performing a weighted sum of the second metric per unit time for the first clock domain and the second metric per unit time for the second clock domain, wherein the weight of the weighted sum is determined based on a frequency ratio of the first clock and the second clock, or a ratio of clock cycle counts into which the first clock and the second clock are input.

In one embodiment, the integrated metric may be calculated based on the equation below:

$${M}_{tot} = \frac{{M}_{A} \cdot {N}_{A} \cdot {f}_{A} + {M}_{B} \cdot {N}_{B} \cdot {f}_{B}}{{N}_{A} \cdot {f}_{A} + {N}_{B} \cdot {f}_{B}}$$

wherein Mₜₒₜ refers to the integrated metric, M_{A} refers to the second metric per unit time for the first clock domain, N_{A} refers to the number of flip-flops driven by the first clock, f_{A} refers to the frequency of the first clock, M_{B} refers to the second metric per unit time for the second clock domain, N_{B} refers to the number of flip-flops driven by the second clock, and f_{B} refers to the frequency of the second clock.

### Effects of the Invention

According to the present disclosure, by providing a metric that reflects not only clock gating status but also data switching status simultaneously, a user may efficiently apply clock gating and, consequently, achieve low-power design during the design process of an integrated circuit.

Further, according to another aspect of the present disclosure, by providing an interfacing method capable of efficiently displaying various metrics related to clock gating, the user may intuitively and easily confirm information related to clock gating.

### BRIEF DESCRIPTION OF THE DRAWINGS

FIG. 1 is a block diagram illustrating a system according to an exemplary embodiment of the present disclosure.

FIG. 2 is a flowchart illustrating an interfacing method according to an exemplary embodiment of the present disclosure.

FIG. 3 is a block diagram illustrating an integrated circuit according to an exemplary embodiment of the present disclosure.

FIG. 4 is a timing diagram illustrating signals in the integrated circuit according to an exemplary embodiment of the present disclosure.

FIG. 5 is a view illustrating a graphic interface according to an exemplary embodiment of the present disclosure.

FIG. 6 is a view illustrating a graphic interface according to an exemplary embodiment of the present disclosure.

FIG. 7 is a view illustrating a graphic interface according to an exemplary embodiment of the present disclosure.

FIG. 8 is a view illustrating a graphic interface according to an exemplary embodiment of the present disclosure.

FIG. 9 is a view illustrating a graphic interface according to an exemplary embodiment of the present disclosure.

FIG. 10 is a view illustrating a graphic interface according to an exemplary embodiment of the present disclosure.

FIG. 11 is a flowchart illustrating an interfacing method according to an exemplary embodiment of the present disclosure.

FIG. 12 is a block diagram illustrating a system according to an exemplary embodiment of the present disclosure.

### DETAILED DESCRIPTION

Hereinafter, preferred embodiments of the present disclosure will be described in detail with reference to the accompanying drawings. The advantages, features, and methods of achieving them will become clear with reference to the embodiments described below and the drawings. However, the spirit of the present disclosure is not limited to the following embodiments and may be realized in various forms. The following embodiments are merely provided so that the spirit of the disclosure can be fully conveyed to those skilled in the art, and the scope of the disclosure is defined only by the claims.

When reference numerals are assigned to elements in the drawings, the same numerals refer to the same or equivalent elements throughout the drawings unless stated otherwise. Descriptions of well-known components or functions that might obscure the gist of the disclosure are omitted.

Unless otherwise defined, all terms (including technical and scientific terms) used herein have the same meanings commonly understood by one of ordinary skill in the art. Terms defined in commonly used dictionaries are to be interpreted as having meanings consistent with their ordinary usage and are not to be interpreted in an idealized or overly formal sense unless explicitly defined herein. Singular terms include the plural form unless the context clearly dictates otherwise.

In describing the components of the disclosure, terms such as first, second, A, B, (a), (b), and the like may be used to distinguish components, but such terms do not limit the nature, order, or sequence of the components. When a component is described as being “connected,” “coupled,” or “joined” to another component, that connection may be direct or indirect via another component.

The term “comprises” (and variants such as “comprising”) specifies the presence of stated features, integers, steps, operations, or elements but does not preclude the presence or addition of one or more other features, integers, steps, operations, or elements.

Components included in one embodiment and components having common functions may be described using the same terminology in other embodiments. Unless otherwise stated, the descriptions set forth in one embodiment may also apply to other embodiments, and specific descriptions may be omitted to the extent that they are overlapping or can be readily understood by those of ordinary skill in the art.

Hereinafter, preferred embodiments of the present invention will be described in detail with reference to the accompanying drawings.

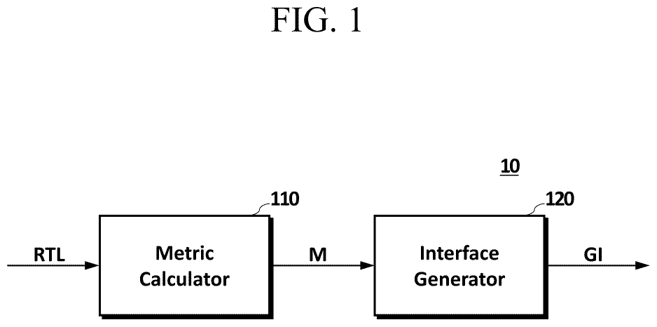

FIG. 1 is a block diagram illustrating a system according to an exemplary embodiment of the present disclosure.

Referring to FIG. 1, a system 10 may include various configurations used to design an integrated circuit (IC). The system 10 may be implemented by servers, PCs, cellular phones, smart phones, laptops, navigation devices, PCS terminals, GSM, PDC, PHS, PDAS, IMT-2000, CDMA-2000, W-CDMA, WiBro terminals, smart pads, tablet PCs, and other terminals.

The integrated circuit may operate based on clock gating and may be divided into a clock gating input cone and a clock gating domain centered on a clock gating cell. The clock gating input cone may be configured to control a clock gating enable signal in response to an input signal. For example, the clock gating input cone may be configured to control the clock gating enable signal to a logic low or a logic high.

The clock gating cell is configured to stop and resume the supply of a clock to the clock gating domain in response to the clock gating enable signal. For example, the clock gating cell may be configured to receive a clock and to output the received clock to the clock gating domain in response to the clock gating enable signal.

The clock gating domain may be configured to operate in response to the gated clock. For example, the clock gating domain may output an output signal in response to the gated clock. When the clock gating cell stops output of the gated clock, the clock gating domain may stop operation. For example, the clock gating domain may stop operation while retaining data in response to the stoppage of the clock output of the clock gating cell. Accordingly, dynamic power consumption of the clock gating domain may be prevented.

In the present disclosure, the clock gating domain may refer to a fan-out logic cone in which the supply of a gated clock is controlled by a single clock gating cell, and the clock domain may refer to at least one clock gating domain to which a single clock is supplied.

In the present disclosure, operations of the system 10 (or components thereof) may refer to an operation performed by a processor included in the system 10 based on a computer program including at least one instruction stored in a storage device included in the system 10. The storage may include non-volatile memory, volatile memory, flash memory, an HDD, or an SSD. The processor may include at least one of a CPU, GPU, NPU, RAM, ROM, system bus, or application processor.

The system 10 may include a metric calculator 110 and an interface generator 120. The metric calculator 110 and the interface generator 120 may be software modules defined as functional units performed by a processor included in the system 10 based on a computer program. The operations performed by the metric calculator 110 and the interface generator 120 may be carried out by separate software modules through a plurality of hardware components or through a single hardware component.

The metric calculator 110 may receive a Register Transfer Level (RTL) circuit and may calculate a metric M according to predetermined methods. The metric M may be an index such as ICGE or IOCGR representing a clock gating ratio or the potential for further clock gating.

In one embodiment, the metric calculator 110 may calculate the metric M by additionally considering a data holding time during which the clock is not gated and input data does not switch, in addition to a clock gating time during which the clock is gated. According to an embodiment of the present disclosure, by additionally considering the data holding time in the metric M, it is possible to inform the user of time intervals where additional clock gating can be applied. As a result, the user may optimize power consumption by applying further clock gating using the metric M.

The interface generator 120 may generate a graphic interface (GI) based on the metric M and may provide the GI to the user. The GI may refer to various types of visual data for efficiently presenting the metric M to the user, and in one example, may be a graph representing the metric M over time.

According to an embodiment of the present disclosure, indicators related to the clock gating may be presented through a time-based GI, and the user may be guided to intuitively perform design modifications for power consumption optimization by identifying the indicators related to the clock gating based on the visual data.

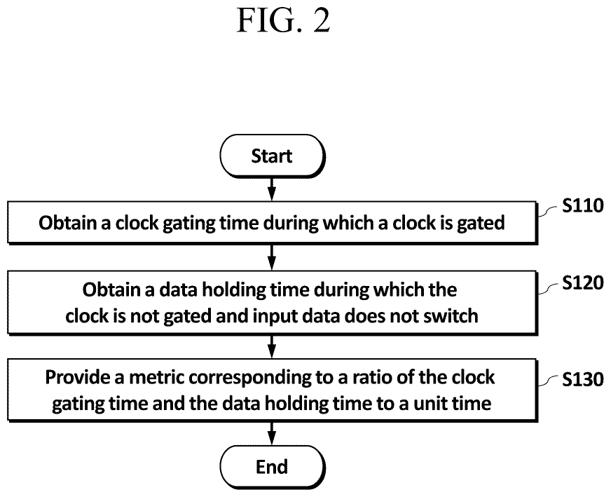

FIG. 2 is a flowchart illustrating an interfacing method according to an exemplary embodiment of the present disclosure. More specifically, FIG. 2 may illustrate a method by which the system 10 provides the metric M.

Referring to FIG. 2, the system 10 may obtain a clock gating time during which a clock is gated, step S110. The clock gating time may refer to a period during which the clock applied to a register or flip-flop is blocked by a clock gating cell.

The system 10 may obtain a data holding time during which the clock is not gated and input data does not switch, step S120. The system 10 may also provide a metric M corresponding to a ratio of the clock gating time and the data holding time to a unit time, step S130.

In one embodiment, the metric M may be determined according to Equation 1 below, and the metric M may be referred to as Ideal Clock Gating Efficiency (ICGE) or Ideal Operational Clock Gating Ratio (IOCGR).

$$M = \frac{{t}_{g} + {t}_{c}}{{t}_{s}} \qquad [ Equation 1 ]$$

(M refers to the metric, t_{g} refers to the clock gating time, t_{c} refers to the data holding time, and tₛ refers to the unit time)

The data holding time refers to a period during which the same data is continuously output while the data is maintained, even though clock gating is not applied, i.e., even though a clock is not input. According to the principles of registers or flip-flops, in a period where the data remains unchanged, the same operation can be performed even though a clock is not input. Therefore, the data holding time may correspond to a time period during which additional application of clock gating is feasible.

According to an embodiment of the present disclosure, by providing the metric using the data holding time to the user, the user may identify additional clock gating time that can be applied by using the metric M together with conventional metrics such as CGE, thereby being guided to achieve an optimal power consumption design. In addition, unlike general metrics such as CGE, the proposed metric uses the unit time as a denominator, enabling uniform comparison across the entire circuit and allowing for a comprehensive metric representing the overall circuit.

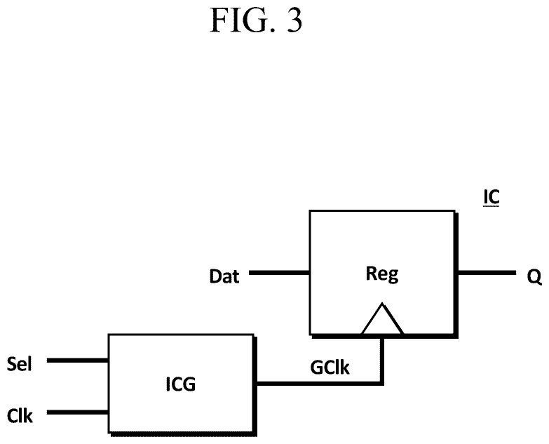

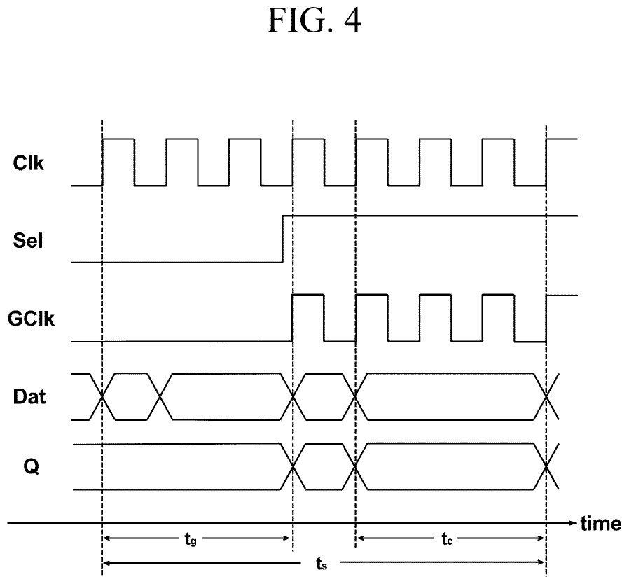

FIG. 3 is a block diagram illustrating an integrated circuit according to an exemplary embodiment of the present disclosure, and FIG. 4 is a timing diagram illustrating signals in the integrated circuit according to an exemplary embodiment of the present disclosure.

Referring to FIG. 3, the integrated circuit (IC) may include a register Reg and a clock gating cell ICG. The clock gating cell ICG may receive a source clock Clk and gate the source clock Clk based on a select signal Sel. In one example, when the clock gating cell ICG receives a logic high ‘1’ as the select signal Sel, the clock gating cell ICG may not gate the source clock Clk, and accordingly, a gating clock GClk may receive the same signal as the source clock Clk. In another example, when the clock gating cell ICG receives a logic low ‘0’ as the select signal Sel, the clock gating cell ICG may gate the source clock Clk, and accordingly, the gating clock GClk may not receive the source clock Clk.

The register Reg may latch input data Dat and may output output data Q based on the gating clock GClk. Although the register Reg is illustrated in FIG. 3, the technical idea of the present disclosure may also be applicable to an example including a flip-flop.

Referring to FIG. 4, various signals may be input to the integrated circuit (IC). The integrated circuit (IC) may receive a source clock Clk during a unit time tₛ, and the gating clock GClk may remain at a logic low ‘0’ based on a logic low ‘0’ of the select signal Sel. In this situation, even if the input data Dat switches, the output data Q may not switch and maintain a constant value. In the present specification, such a condition—where the source clock Clk is not delivered to the register Reg by the clock gating cell ICG, and as a result, the output data Q does not switch—may be referred to as “gating,” and a clock cycle gated by the select signal Sel may be referred to as a clock gating time t_{g}.

When the source clock Clk is prevented from being delivered to the register Reg through gating, the corresponding portion of the power consumption caused by the source clock Clk can be reduced. This effect constitutes the fundamental purpose of implementing clock gating.

Even in a period where clock gating is not applied, a period may occur in which the output data Q does not switch, due to the input data Dat not switching. In the present specification, such a clock cycle—where the gating clock GClk is supplied because clock gating is not applied, but the output data Q does not change due to the absence of variation in the input data Dat—may be referred to as a data holding time t_{c}.

The system 10 may determine the metric M as a ratio of the clock gating time t_{g} and the data holding time t_{c} to the unit time tₛ, as described in Equation 1. According to an embodiment of the present disclosure, by setting the metric M in the above-described manner, the system 10 may obtain an indicator representing a period in which the output data Q does not actually switch, and by utilizing this in relation to power consumption, an indicator capable of substantially estimating power consumption may be obtained.

In addition, the data holding time the may correspond to a period in which the same result may be obtained even if additional clock gating is applied, since the data does not switch regardless of whether the clock is input to the register Reg. According to an embodiment of the present disclosure, an indicator corresponding to the data holding time t_{c} may be obtained by utilizing the metric M together with other indicators related to the gating ratio (e.g., CGE or OCGR). Since such an indicator represents a period in which additional clock gating can be applied, it is possible to guide the user to apply additional clock gating using the metric M, thereby enabling optimization of power consumption.

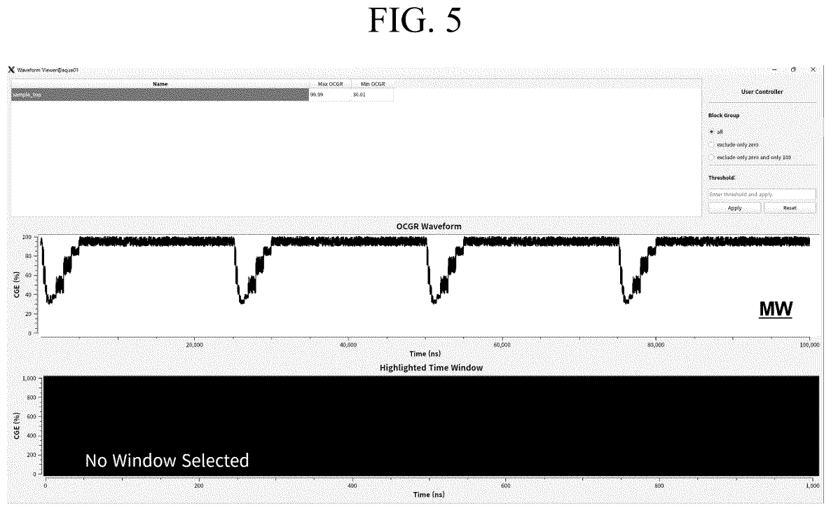

FIG. 5 is a view illustrating a graphic interface according to an exemplary embodiment of the present disclosure.

Referring to FIG. 5, the graphic interface (GI) may include a metric window (MW), and a graph representing the metric M, calculated by the metric calculator 110, by time period may be displayed through the metric window (MW). The above-described metric M may include not only ICGE described in Equation 1, but also various other metrics such as CGE, CGEE, CGR, and OCGR. According to an embodiment of the present disclosure, by presenting the metric M by time period to the user, the user may identify time periods in which the metric M drops, and may optimize the metric M by modifying the circuit design corresponding to those specific time periods.

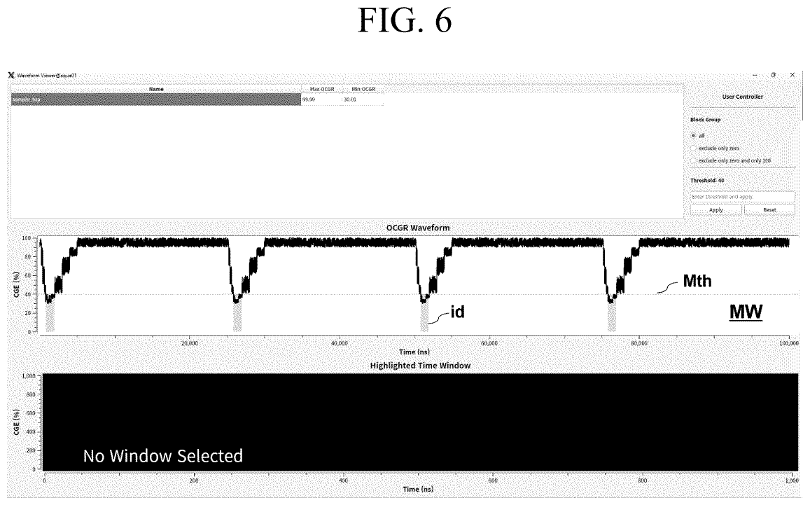

FIG. 6 is a view illustrating a graphic interface according to an exemplary embodiment of the present disclosure.

Referring to FIG. 6, the system 10 may receive a predetermined target metric value (Mth) and identify time periods in which the metric M is equal to or lower than the target metric value (Mth). In addition, the system 10 may display, in the metric window (MW), the time periods in which the metric M is equal to or lower than the target metric value (Mth) using an indicator (id). In one example, the indicator (id) may represent the corresponding time periods with a specific color.

According to an embodiment of the present disclosure, by visually presenting the time periods in which the metric M is lower than the target metric value (Mth) using the indicator (id), the user may intuitively identify the periods where the metric M needs to be improved, and optimization of the integrated circuit may be achieved.

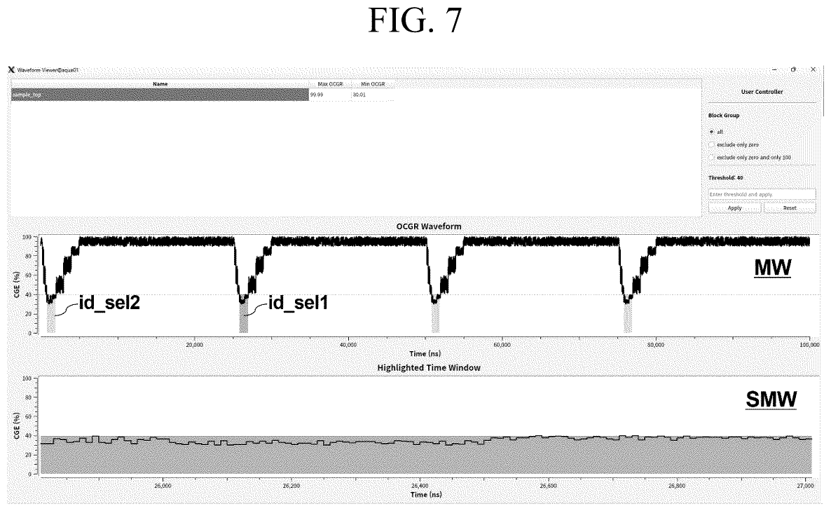

FIG. 7 is a view illustrating a graphic interface according to an exemplary embodiment of the present disclosure.

Referring to FIG. 7, the system 10 may receive a selection instruction for an indicator (id) from the user. In one example, the user may select the indicator (id) by clicking on indicator (id). In one embodiment, the system 10 may enlarge the time period corresponding to a first selected indicator (id_sel1) and display it in a sub metric window (SMW), and the first selected indicator (id_sel1) and the sub metric window (SMW) may be represented in the same color (e.g., dark green).

According to an embodiment of the present disclosure, the system 10 may display a graph of the metric M, enlarged for a specific time period selected by the user to allow the user to examine the time period in greater detail, using the same color in the sub metric window (SMW), which is a separate window. This allows the user to examine the desired time period in greater detail while intuitively recognizing the position of the graph displayed in the sub metric window (SMW) within the overall graph.

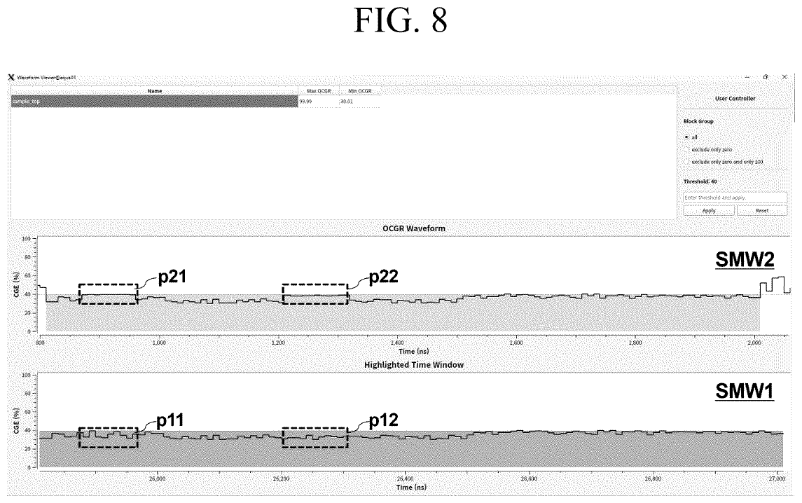

FIG. 8 is a view illustrating a graphic interface according to an exemplary embodiment of the present disclosure.

Referring to FIG. 8, a first sub metric window (SMW1) may represent a time period corresponding to the first selected indicator (id_sel1) of FIG. 7, and a second sub metric window (SMW2) may represent a time period corresponding to the second selected indicator (id_sel2) of FIG. 7.

The time periods of the first selected indicator (id_sel1) and the second selected indicator (id_sel2), as shown in the metric window (MW) of FIG. 7, may appear similar. However, as shown in FIG. 8, a detailed view reveals that a sub period 11 (p11) and a sub period 12 (p12) of the first selected indicator (id_sel1) may differ from a sub period 21 (p21) and a sub-period 22 (p22) of the second selected indicator (id_sel2). According to an embodiment of the present disclosure, by providing an enlarged view of the metric M by time period and simultaneously displaying metric M graphs for multiple time periods, the system may provide an environment in which the user can compare the metric M across different time periods.

In one embodiment, the system 10 may display and provide to the user corresponding periods from two time ranges that exhibit different metric values (e.g., p11-p21, p12-p22), thereby providing an environment in which the user can efficiently compare those periods.

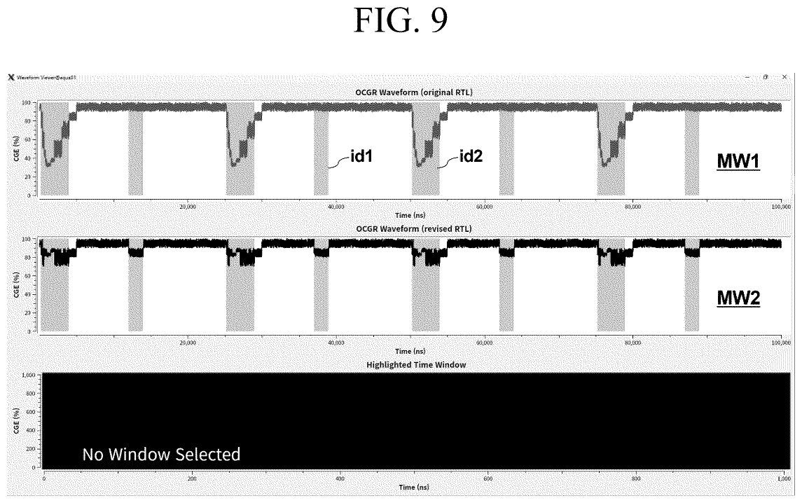

FIG. 9 is a view illustrating a graphic interface according to an exemplary embodiment of the present disclosure.

Referring to FIG. 9, the graphic interface (GI) may include a first metric window (MW1) representing a first metric (M1) and a second metric window (MW2) representing a second metric (M2). In one example, the first metric (M1) is a metric calculated based on a first RTL circuit, and the second metric (M2) is a metric calculated based on a second RTL circuit, which may be a modified version of the first RTL circuit.

In one embodiment, the system 10 may compare the first metric M1 and the second metric M2, and display periods where the first metric (M1) has a higher value than the second metric (M2) using a first indicator (id1) (e.g., highlighted in red), and display periods where the first metric (M1) has a smaller value than the second metric (M2) using a second indicator (id2) (e.g., highlighted in green).

According to an embodiment of the present disclosure, the metrics for RTL circuits of different versions can be compared simultaneously in separate metric windows. Furthermore, by representing improved periods (i.e., where the metric has increased after design modification) and degraded periods (i.e., where the metric has decreased) using different indicators, the user can intuitively identify whether the RTL circuit has been improved and where such improvements or degradations have occurred.

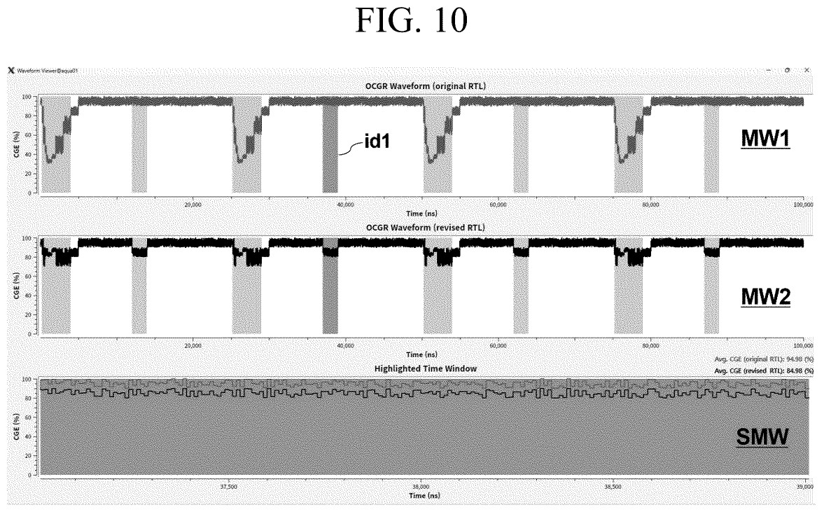

FIG. 10 is a view illustrating a graphic interface according to an exemplary embodiment of the present disclosure.

Referring to FIG. 10, the graphic interface (GI) may include a first metric window (MW1) representing a first metric (M1), a second metric window (MW2) representing a second metric (M2), and a sub metric window (SMW) corresponding to a first indicator (id1).

The sub metric window (SMW) may represent a metric for a period in which the first metric (M1) is higher than the second metric (M2), i.e., a degraded period resulting from the design modification. In one embodiment, the sub metric window (SMW) may use the same color as the first indicator (id1) (e.g., red highlight), thereby providing an environment in which the user can intuitively recognize the corresponding period of the sub metric window (SMW) within the entire graph.

In addition, in one embodiment, the sub metric window (SMW) may display both versions of the metric M1 and the metric M2 for the period corresponding to the first indicator (id1), thereby providing an environment in which the user can simultaneously identify the extent of degradation and point-by-point metric difference.

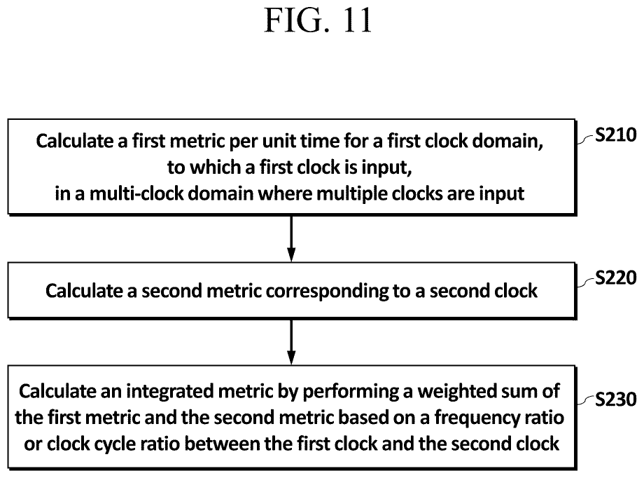

FIG. 11 is a flowchart illustrating an interfacing method according to an exemplary embodiment of the present disclosure. More specifically, FIG. 11 illustrates a method for calculating an integrated metric for a multi-clock domain in which different clocks are input.

Referring to FIG. 11, the system 10 may calculate a first metric per unit time for a first clock domain, to which a first clock is input, in a multi-clock domain where multiple clocks are input, step S210. The system 10 may also calculate a second metric per unit time for a second clock domain, to which a second clock is input, step S220. The system 10 may display the first metric and the second metric for each of the first clock domain and second clock domain, and may calculate an integrated metric by performing a weighted sum of the first metric and the second metric based on a frequency ratio or clock cycle ratio between the first clock and the second clock, step S230.

In one embodiment, the integrated metric (Mtot) may be calculated based on the Equation 2 below.

$${M}_{tot} = \frac{{M}_{A} \cdot {N}_{A} \cdot {f}_{A} + {M}_{B} \cdot {N}_{B} \cdot {f}_{B}}{{N}_{A} \cdot {f}_{A} + {N}_{B} \cdot {f}_{B}} \qquad [ Equation 2 ]$$

(Mtot refers to the integrated metric, M_{A} refers to the first metric; N_{A} refers to the number of flip-flops/registers driven by the first clock, f_{A} refers to the frequency of the first clock, M_{B} refers to the second metric, N_{B} refers to the number of flip-flops/registers driven by the second clock, and f_{B} refers to the frequency of the second clock.)

In a multi-clock domain, if 50% is derived as a first metric for a first clock with a first frequency, and 100% is derived as a second metric for a second clock with a second frequency, the conventional approach calculates the integrated metric as a simple average of 75%. However, from the perspective of dynamic power consumption caused by clocks, the number of gating opportunities differs depending on the frequency, and thus a simple average is insufficient to accurately reflect the integrated metric.

According to an embodiment of the present disclosure, the system 10 may calculate an integrated metric for a multi-clock domain not by simply averaging the metrics corresponding to the different clocks, but by taking into account the frequency of each clock and the number of flip-flops/registers driven by each clock. As a result, a more practically meaningful integrated metric can be obtained.

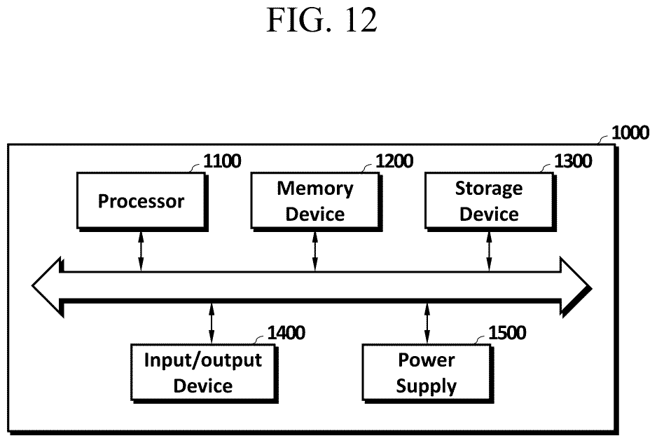

FIG. 12 is a block diagram illustrating a system according to an exemplary embodiment of the present disclosure.

Referring to FIG. 12, a system 1000 may include a processor 1100, a memory device 1200, a storage device 1300, input/output device 1400, and power supply 1500. Meanwhile, although not illustrated in FIG. 12, the system 1000 may further include ports capable of communicating with devices such as a video card, sound card, memory card, USB device, or other electronic devices.

As such, the processor 1100, memory device 1200, storage device 1300, input/output device 1400, and power supply 1500 included in the system 1000 may perform the operations of the system 10 according to embodiments based on the technical idea of the present disclosure. Specifically, the operations of the system 1000 described in FIGS. 1 to 11 may refer to operations performed by the processor 1100 based on a computer program including at least one instruction stored in the memory device 1200 or the storage device 1300.

The processor 1100 may perform specific computations or tasks. According to an embodiment, the processor 1100 may include at least one of a microprocessor, a Central Processing Unit (CPU), a Graphic Processing Unit (GPU), a Neural Processing Unit (NPU), Random Access Memory (RAM), Read-Only Memory (ROM), a system bus, and an application processor. The processor 1100 may communicate with the memory device 1200, the storage device 1300, and the input/output device 1400 through a bus, such as an address bus, control bus, and data bus. According to an embodiment, the processor 1100 may also be connected to an expansion bus, such as a Peripheral Component Interconnect (PCI) bus.

The memory device 1200 may store data necessary for the operation of the system 1000. For example, the memory device 1200 may be implemented using DRAM (Dynamic Random Access Memory), mobile DRAM, SRAM (Static Random Access Memory), PRAM (Phase-change RAM), FRAM (Ferroelectric RAM), RRAM (Resistive RAM), and/or MRAM (Magnetoresistive RAM). The storage device (1300) may include a solid state drive (SSD), a hard disk drive (HDD), a CD-ROM, and the like. The memory device 1200 and the storage device 1300 may store a program related to the interfacing method described in FIGS. 1 to 11.

The input/output device 1400 may include input means such as a keyboard, keypad, or mouse, and output means such as a printer or display. The power supply 1500 may supply an operating voltage required for the operation of the system 1000.

As described above, exemplary embodiments have been disclosed in the drawings and the specification. Although specific terms have been used to describe the embodiments in the present specification, such terms are used merely for the purpose of describing the technical idea of the present disclosure and are not intended to limit the meaning of the terms or the scope of the present disclosure as set forth in the claims. Accordingly, those skilled in the art will appreciate that various modifications and equivalent other embodiments may be made based on the present disclosure. Therefore, the true scope of technical protection of the present disclosure should be defined by the technical spirit described in the appended claims.

What is claimed is:

1. An interfacing method for Register Transfer Level (RTL) design simulation of an integrated circuit performed by a processor, the method comprising:
obtaining a clock gating time during which a clock is gated with respect to the integrated circuit;
obtaining a data holding time during which the clock is not gated and input data does not switch; and
interfacing a first metric corresponding to a ratio of the clock gating time and the data holding time to a unit time to a user device.

2. The method of claim 1, wherein the first metric is determined according to an equation:
$$M = \frac{{t}_{g} + {t}_{c}}{{t}_{s}}$$
wherein M refers to the first metric, t_{g} refers to the clock gating time, t_{c} refers to the data holding time, and tₛ refers to the unit time.

3. The method of claim 1, further comprising:
calculating a second metric corresponding to a clock gating ratio;
receiving a scenario time; and
interfacing a graph of the second metric per unit time, for the scenario time.

4. The method of claim 3, further comprising:
receiving a target metric value; and
indicating, using an indicator, a unit time during which the second metric does not satisfy the target metric value.

5. The method of claim 4, further comprising:
receiving a selection instruction for the indicator; and
displaying an expanded graph in which a time axis of a unit time corresponding to the indicator is extended based on the selection instruction,
wherein the indicator highlights corresponding time interval with a predetermined color and the expanded graph is also highlighted with the predetermined color.

6. The method of claim 3, wherein the interfacing the graph of the second metric comprises:
calculating the second metric per unit time for a first RTL circuit;
providing a first graph depicting the second metric per unit time for the first RTL circuit along a time flow of the clock;
calculating the second metric per unit time for a second RTL circuit;
providing a second graph depicting the second metric per unit time for the second RTL circuit along a time flow of the clock; and
indicating unit times that are not identical between the first graph and the second graph.

7. The method of claim 6,
wherein the indicating unit times that are not identical between the first graph and the second graph comprises:
highlighting, with a first color, unit times in which the second metric per unit time for the first RTL circuit is higher than the second metric per unit time for the second RTL circuit; and
highlighting, with a second color, unit times in which the second metric per unit time for the first RTL circuit is lower than the second metric per unit time for the second RTL circuit.

8. The method of claim 3,
wherein the interfacing the graph of the second metric comprises:
calculating the second metric per unit time for a first clock domain in the RTL circuit to which a first clock is applied;
calculating the second metric per unit time for a second clock domain in the RTL circuit to which a second clock is applied; and
indicating the second metric for each of the first clock domain and the second clock domain.

9. The method of claim 8,
wherein the interfacing the graph of the second metric further comprises:
calculating an integrated metric by performing a weighted sum of the second metric per unit time for the first clock domain and the second metric per unit time for the second clock domain,
wherein the weight of the weighted sum is determined based on a frequency ratio of the first clock and the second clock, or a ratio of clock cycle counts into which the first clock and the second clock are input.

10. The method of claim 9,
wherein the integrated metric is calculated based on the equation below:
$${M}_{tot} = \frac{{M}_{A} \cdot {N}_{A} \cdot {f}_{A} + {M}_{B} \cdot {N}_{B} \cdot {f}_{B}}{{N}_{A} \cdot {f}_{A} + {N}_{B} \cdot {f}_{B}}$$
wherein Mₜₒₜ refers to the integrated metric, M_{A} refers to the second metric per unit time for the first clock domain, N_{A} refers to the number of flip-flops driven by the first clock, f_{A} refers to the frequency of the first clock, M_{B} refers to the second metric per unit time for the second clock domain, N_{B} refers to the number of flip-flops driven by the second clock, and f_{B} refers to the frequency of the second clock.
